(19) United States
(12) Patent Application Publication
(10) Pub. No.: US 2024/0230810 A1
(43) Pub. Date: Jul. 11, 2024

(54) System and Method for Quantitative Magnetic Resonance Imaging Using a Deep Learning Network

(71) Applicant: The Regents of the University of California, Oakland, CA (US)

(72) Inventors: Shu-Fu Shih, Los Angeles, CA (US); Holden H. Wu, Los Angeles, CA (US)

(21) Appl. No.: 18/554,397

(22) PCT Filed: Apr. 11, 2022
(86) PCT No.: PCT/US2022/024297

§ 371 Date: Oct. 6, 2023

Related U.S. Application Data
(60) Provisional application No. 63/173,319, filed on Apr. 9, 2021.

(51) Int. Cl. G01R 33/56; G01R 33/48; G06T 7/00

(52) U.S. Cl. CPC G01R 33/5608; G01R 33/4828; G06T 7/0016; G06T 2207/20081; G06T 2207/20084; G06T 2207/30056

(57) ABSTRACT

A method for generating magnetic resonance imaging (MRI) quantitative parameter maps includes receiving at least one multi-contrast magnetic resonance (MR) image of a subject, providing the image to an artifact suppression deep learning network of a two-stage deep learning network and generating at least one multi-contrast MR image with suppressed undersampling artifacts using the artifact suppression deep learning network. The method further includes providing the at least one multi-contrast MR image with suppressed undersampling artifacts to a parameter mapping deep learning network of the two-stage deep learning network, generating at least one quantitative MR parameter map and generating an uncertainty estimation map for the at least one quantitative MR parameter map using the parameter mapping deep learning network. The method further includes displaying at least one multicontrast MR image with suppressed undersampling artifacts, at least one quantitative MR parameter map, and the corresponding uncertainty estimation map on a display.

### CROSS-REFERENCE TO RELATED APPLICATIONS

This application is based on, claims priority to, and incorporates herein by reference in its entirety U.S. Ser. No. 63/173,319 filed Apr. 9, 2021 and entitled “Deep-Learning Framework for Quantitative Magnetic Resonance Imaging.”

### STATEMENT REGARDING FEDERALLY SPONSORED RESEARCH

This invention was made with government support under Grant Number DK124417, awarded by the National Institutes of Health. The government has certain rights in the invention.

### BACKGROUND

Quantitative magnetic resonance imaging (MRI) typically uses acquisition of multi-contrast images followed by signal fitting to generate quantitative parameter maps. This technique requires longer acquisition time than qualitative MRI and computationally expensive algorithms for signal fitting. Quantitative MRI can be accelerated by acquiring an undersampled set of MRI k-space data, but data undersampling leads to artifacts that obscure image features and impact quantification accuracy. Although constrained reconstruction methods (e.g., compressed sensing) can reduce the undersampling artifacts, they require iterative algorithms which are time consuming.

One example of quantitative MRI is fat quantification by chemical shift-encoded MRI, which is used to diagnose diseases such as non-alcoholic fatty liver disease (NAFLD). NAFLD is the most prevalent chronic liver disease and has become a global health burden, compounded by rising rates of obesity. NAFLD represents a spectrum of diseases ranging from fat accumulation in the liver to the more severe non-alcoholic steatohepatitis (NASH) with hepatic inflammation. NAFLD is also associated with abnormal iron regulation and can lead to excessive hepatic iron deposition with increased risks of cirrhosis and hepatocellular carcinoma. Biopsy is considered the standard technique for diagnosing NAFLD and other liver diseases. However, biopsy suffers from sampling bias and the invasive procedure can cause serious complications.

MRI enables noninvasive evaluation of liver fat and iron, for example, hepatic steatosis and iron overload, by quantifying proton-density fat fraction (PDFF) and R₂*, using, for example, chemical-shift-encoded MRI. Chemical shift-encoded MRI requires image acquisition at multiple echo times (TEs), fitting the acquired data to a multiparametric nonlinear fat-water signal model, and calculation of PDFF maps. For example, multi-echo Dixon techniques acquire and fit data to a signal model that accounts for the multi-peak fat spectrum and R₂* component. Conventional Dixon MRI techniques often rely on a multi-echo 3D Cartesian sequence, which is sensitive to subject motion and requires breath-holding (10-25 sec) to avoid artifacts. The breath-holding requirement limits the volumetric coverage and resolution, and can be challenging for patients. Non-Cartesian radial MRI with improved motion robustness can enable free-breathing liver fat and iron quantification, but can require 2-5 min scans.

Self-gated free-breathing multi-echo stack-of-radial MRI techniques quantify liver fat and R₂* without breath-holding. Recently, a multi-echo 3D stack-of-radial MRI technique with improved motion robustness was developed for free-breathing liver PDFF and R₂* quantification (or mapping) and demonstrated accurate results in subjects with NAFLD. To compensate for respiratory motion in free-breathing radial data acquisition, self-gating can be used to reconstruct images from a subset of data with consistent motion behavior (e.g., at end expiration). However, rejecting data from other respiratory motion states introduces radial undersampling artifacts (e.g., radial undersampling streaking artifacts) in the images and corresponding PDFF and R₂* maps, and degrades the image quality and quantification accuracy. These artifacts can be mitigated by data oversampling (e.g., acquiring more radial spokes) or using constrained reconstruction (e.g., compressed sensing (CS)), but these strategies require longer acquisition and/or computational time.

In addition to challenges in data acquisition, accurate and rapid signal fitting is another challenge in PDFF and R₂* quantification. Due to the non-convex structure of the signal model and ambiguities in resonant frequencies of water/fat protons with respect to B₀ field variations, signal fitting can converge to a local minimum solution and lead to fat-water swaps. To solve this problem, state-of-the-art graph-cut (GC)-based methods impose smoothness constraints on the field map and use optimization algorithms to reduce the occurrence of fat-water swaps. However, the GC-based algorithms are computationally expensive with computation time on the order of 10 sec/slice.

### SUMMARY

In accordance with an embodiment, a method for generating magnetic resonance imaging (MRI) quantitative parameter maps includes receiving at least one multi-contrast magnetic resonance (MR) image of a subject, providing the at least one multi-contrast MR image of the subject to an artifact suppression deep learning network of a two-stage deep learning network and generating at least one multi-contrast MR image with suppressed undersampling artifacts using the artifact suppression deep learning network to suppress undersampling artifacts in the at least one multi-contrast MR image of the subject. The method further includes providing the at least one multi-contrast MR image with suppressed undersampling artifacts to a parameter mapping deep learning network of the two-stage deep learning network, generating at least one quantitative MR parameter map based on the at least one multi-contrast MR image with suppressed undersampling artifacts using the parameter mapping deep learning network and generating an uncertainty estimation map for the at least one quantitative MR parameter map using the parameter mapping deep learning network. The method further includes displaying at least one of the at least one multi-contrast MR image with suppressed undersampling artifacts, the at least one quantitative MR parameter map, and the corresponding uncertainty estimation map on a display.

In accordance with another embodiment, a system for generating magnetic resonance imaging (MRI) quantitative parameter maps includes an input for receiving at least one multi-contrast magnetic resonance (MR) image of a subject: a two-stage deep learning network, and a display. The two-stage deep learning network includes an artifact suppression deep learning network configured to generate at least one multi-contrast MR image with suppressed undersampling artifacts using the at least one multi-contrast MR image of the subject and a parameter mapping deep learning network coupled to the artifact suppression deep learning network. The parameter mapping deep learning network may be configured to generate at least one quantitative MR parameter map based on the at least one multi-contrast MR image with suppressed undersampling artifacts and to generate an uncertainty estimation map for the at least one quantitative MR parameter map. The display may be configured to display at least one of the at least one multi-contrast MR image with suppressed undersampling artifacts, the at least one quantitative MR parameter map, and the corresponding uncertainty estimation map.

### BRIEF DESCRIPTION OF THE DRAWINGS

The present invention will hereafter be described with reference to the accompanying drawings, wherein like reference numerals denote like elements.

FIG. 1 is a schematic diagram of an example magnetic resonance imaging (MRI) system in accordance with an embodiment:

FIG. 2 is a block diagram of a system for generating MR images, quantitative parameter maps, and uncertainty maps using a deep learning network in accordance with an embodiment:

FIG. 3 illustrates a method for generating MR images, quantitative parameter maps, and uncertainty maps using a deep learning network in accordance with an embodiment:

FIG. 4 illustrates an example method for generating two-dimensional undersampled input images for an artifact suppression deep learning network in accordance with an embodiment:

FIG. 5 illustrates an example method for training an uncertainty aware, physics-driven deep learning network (UP-Network, UP-Net) in accordance with an embodiment:

FIG. 6 illustrates an example method for generating training images and parameter maps for a training process for a deep learning network in accordance with an embodiment:

FIG. 7 illustrates a method for calibrating uncertainty scores from a deep learning network and predicting actual errors for quantitative parameter mapping using the uncertainty scores in accordance with an embodiment; and

FIG. 8 is a block diagram of an example computer system in accordance with an embodiment.

### DETAILED DESCRIPTION

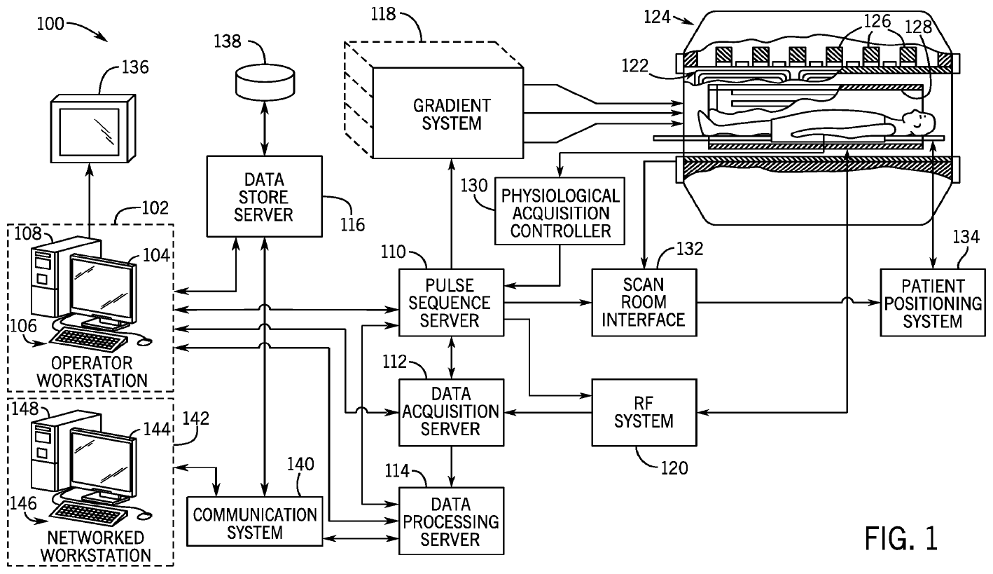

FIG. 1 shows an example of an MRI system 100 that may be used to perform the methods described herein. MRI system 100 includes an operator workstation 102, which may include a display 104, one or more input devices 106 (e.g., a keyboard, a mouse), and a processor 108. The processor 108 may include a commercially available programmable machine running a commercially available operating system. The operator workstation 102 provides an operator interface that facilitates entering scan parameters into the MRI system 100. The operator workstation 102 may be coupled to different servers, including, for example, a pulse sequence server 110, a data acquisition server 112, a data processing server 114, and a data store server 116. The operator workstation 102 and the servers 110, 112, 114, and 116 may be connected via a communication system 140, which may include wired or wireless network connections.

The pulse sequence server 110 functions in response to instructions provided by the operator workstation 102 to operate a gradient system 118 and a radiofrequency (“RF”) system 120. Gradient waveforms for performing a prescribed scan are produced and applied to the gradient system 118, which then excites gradient coils in an assembly 122 to produce the magnetic field gradients Gₓ, G_{y}, and G_{z} that are used for spatially encoding magnetic resonance signals. The gradient coil assembly 122 forms part of a magnet assembly 124 that includes a polarizing magnet 126 and a whole-body RF coil 128.

RF waveforms are applied by the RF system 120 to the RF coil 128, or a separate local coil to perform the prescribed magnetic resonance pulse sequence. Responsive magnetic resonance signals detected by the RF coil 128, or a separate local coil, are received by the RF system 120. The responsive magnetic resonance signals may be amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the prescribed scan and direction from the pulse sequence server 110 to produce RF pulses of the desired frequency, phase, and pulse amplitude waveform. The generated RF pulses may be applied to the whole-body RF coil 128 or to one or more local coils or coil arrays.

The RF system 120 also includes one or more RF receiver channels. An RF receiver channel includes an RF preamplifier that amplifies the magnetic resonance signal received by the coil 128 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} \qquad ( 1 )$$

and the phase of the received magnetic resonance signal may also be determined according to the following relationship:

$$φ = {tan}^{- 1} ( \frac{Q}{I} ) \qquad ( 2 )$$

The pulse sequence server 110 may receive patient data from a physiological acquisition controller 130. By way of example, the physiological acquisition controller 130 may receive signals from a number of different sensors connected to the patient, including electrocardiograph (“ECG”) signals from electrodes, or respiratory signals from a respiratory bellows or other respiratory monitoring devices. These signals may be used by the pulse sequence server 110 to synchronize, or “gate,” the performance of the scan with the subject's heart beat or respiration.

The pulse sequence server 110 may also connect to a scan room interface circuit 132 that receives signals from various sensors associated with the condition of the patient and the magnet system. Through the scan room interface circuit 132, a patient positioning system 134 can receive commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, so that data is not lost by data overrun. In some scans, the data acquisition server 112 passes the acquired magnetic resonance data to the data processor server 114. In scans that require information derived from acquired magnetic resonance data to control the further performance of the scan, the data acquisition server 112 may be programmed to produce such information and convey it to the pulse sequence server 110. For example, during pre-scans, magnetic resonance data may be acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also process magnetic resonance signals used to detect the arrival of a contrast agent in a magnetic resonance angiography (“MRA”) scan. For example, the data acquisition server 112 may acquire magnetic resonance data and processes it in real-time to produce information that is used to control the scan.

The data processing server 114 receives magnetic resonance data from the data acquisition server 112 and processes the magnetic resonance data in accordance with instructions provided by the operator workstation 102. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 114 are conveyed back to the operator workstation 102 for storage. Real-time images may be stored in a data base memory cache, from which they may be output to operator display 104 or a display 136. Batch mode images or selected real time images may be stored in a host database on disc storage 138. When such images have been reconstructed and transferred to storage, the data processing server 114 may notify the data store server 116 on the operator workstation 102. The operator workstation 102 may be used by an operator to archive the images, produce films, or send the images via a network to other facilities.

The MRI system 100 may also include one or more networked workstations 142. For example, a networked workstation 142 may include a display 144, one or more input devices 146 (e.g., a keyboard, a mouse), and a processor 148. The networked workstation 142 may be located within the same facility as the operator workstation 102, or in a different facility, such as a different healthcare institution or clinic.

The networked workstation 142 may gain remote access to the data processing server 114 or data store server 116 via the communication system 140. Accordingly, multiple networked workstations 142 may have access to the data processing server 114 and the data store server 116. In this manner, magnetic resonance data, reconstructed images, or other data may be exchanged between the data processing server 114 or the data store server 116 and the networked workstations 142, such that the data or images may be remotely processed by a networked workstation 142.

The present disclosure describes a system and method for quantitative magnetic resonance imaging (MRI) using a deep learning network (or neural network), in particular, a system and method for generating MRI quantitative parameter maps and corresponding uncertainty maps using a two-stage uncertainty-aware, physics-driven deep learning network (or UP-Net). In some embodiments, the two-stage deep learning network includes two concatenated deep learning networks including an artifact suppression (or image enhancement) deep learning network (or neural network, module or stage) and a parameter mapping deep learning network (or neural network, module, or stage). The two-stage deep learning network can provide for an image-to-image-to-map (IIM) framework. Advantageously, the disclosed system and method for quantitative MRI can suppress MRI undersampling artifacts and generate accurate quantitative parameter maps with a rapid inference time. In addition, the parameter mapping stage may be configured to generate uncertainty maps for corresponding quantitative parameter maps. In some embodiments, the disclosed two-stage deep learning network is configured to generate quantitative parameter maps and uncertainty maps using undersampled input data and images. The uncertainty maps may be configured to estimate pixel-wise uncertainty levels of corresponding quantitative parameter maps for each parameter. For example, an uncertainty map may detect unreliable regions due to low signal-to-noise (SNR) in the input images and data. In some embodiments, the uncertainty maps may be used to predict or detect parameter quantification errors, for example, detect regions with potential quantification errors. In some embodiments, the uncertainty-aware, physics drive deep learning framework combines undersampling artifact suppression, parameter mapping, and uncertainty estimation into one single architecture, which provides for accelerated quantitative MRI. Advantageously, the disclosed two-stage deep learning framework can use shared information between images and maps to achieve sharper spatial features and less blurring in the quantitative maps, based on undersampled input data. In addition, the disclosed system and method for quantitative MRI can accelerate the data acquisition time and can reduce the computational time for parameter mapping.

In some embodiments, the undersampling artifacts are radial MRI undersampling streaking artifacts. In some embodiments, the disclosed system and method for quantitative MRI may be used to evaluate and quantify liver fat, iron, or tissue property changes associated with inflammation, fibrosis, and cirrhosis In some embodiments, the MR parameters that can be quantitatively mapped can include, for example, PDFF, R₂*, T₁, T₂, stiffness, susceptibility, diffusion, chemical exchange, or magnetization transfer.

In some embodiments, the system and method for quantitative MRI may be used to rapidly generate quantitative proton-density fat fraction (PDFF) and/or R₂* maps, along with uncertainty maps, from undersampled free-breathing multi-echo stack-of-radial MRI data. Advantageously, in some embodiments, the disclosed two-stage deep learning network for quantitative MRI can achieve high image quality from undersampled radial data, high accuracy for parameter quantification (e.g., liver fat quantification), and detect uncertainty caused by, for example, noisy input data.

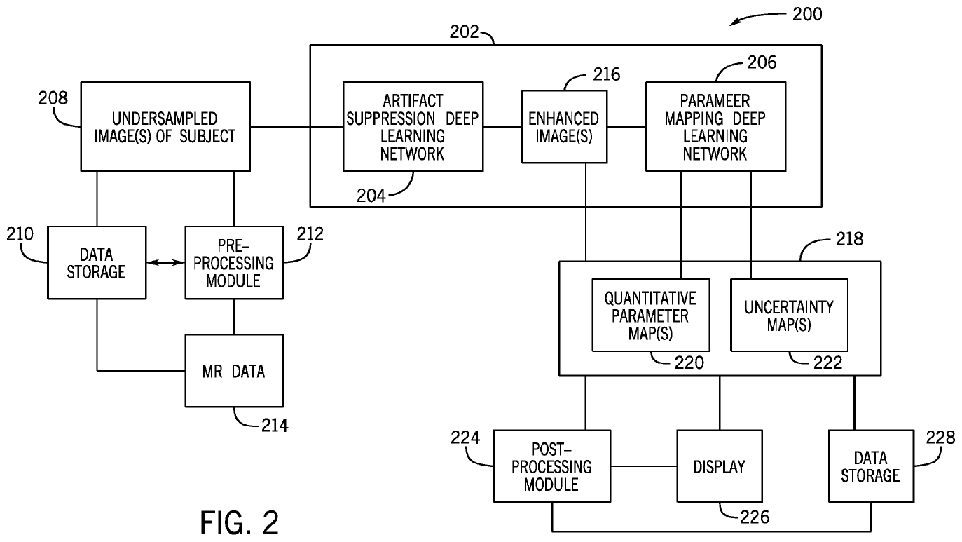

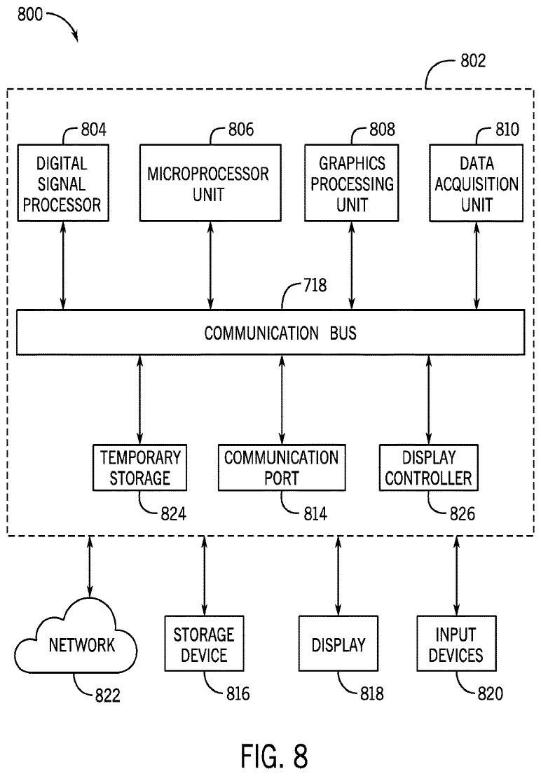

FIG. 2 is a block diagram of a system for generating MR images, quantitative parameter maps, and uncertainty maps using a deep learning network in accordance with an embodiment. The system 200 can include a two-stage uncertainty-aware, physics-driven deep learning network (or UP-Network, UP-Net) 202, an input 208 of one or more undersampled images of a subject (e.g., a region of interest of a subject), data storage 210, a pre-processing module 212, output(s) 218 of the deep learning network 202, a post-processing module 224, a display 226 and data storage 228. The undersampled input image(s) 208 of the subject may be magnetic resonance (MR) images acquired using an MRI system such as, for example, MRI system 100 shown in FIG. 1. In some embodiments, the undersampled images 208 are two-dimensional images, three dimensional images, or images of other dimensions. In some embodiments, the undersampled input images 208 are multi-echo, multi-contrast MR images. In some embodiments, the undersampled input image(s) 208 may be retrieved from data storage (or memory) 210 of system 200, data storage of an imaging system (e.g., disc storage 138 of MRI system 100 show in FIG. 1), or data storage of other computer systems (e.g., storage device 816 of computer system 800 shown in FIG. 8).

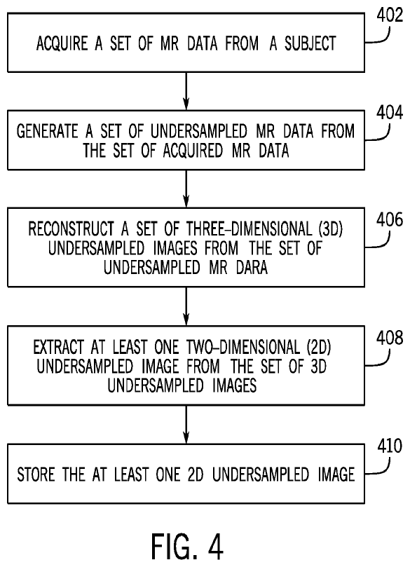

In some embodiments, the undersampled input images 208 may be acquired in real time from a subject using an MRI system (e.g., MRI system 100 shown in FIG. 1). For example, MR data 214 can be acquired from a subject using a pulse sequence performed on the MRI system and configured to acquire multi-echo, multi-contrast MR data. For example, in some embodiments, a free-breathing multi-echo gradient-echo three-dimensional (3D) stack-of-radial pulse sequence can be used to acquire multi-echo, multi-contrast radial MR data from a subject. The acquired MR data 214 may be stored in, for example, data storage 210 of system 200, data storage of an imaging system (e.g., disc storage 138 of MRI system 100 show in FIG. 1), or data storage of other computer systems (e.g., storage device 816 of computer system 800 shown in FIG. 8). The pre-processing module 214 may be configured to reconstruct the undersampled images 208 from the acquired MR 214 data using, for example, known reconstruction methods. In some embodiments, the acquired MR data 214 is nominally fully sampled k-space data and the pre-processing module 212 can be configured to generate a set of undersampled k-space data with desired characteristics which may then be used to reconstruct the undersampled images 208. In some embodiments, the acquired MR data 214 may be undersampled data or nominally oversampled data. Known methods may be used to generate the set of undersampled k-space data from the acquired fully sampled k-space data. In some embodiments, the set of undersampled k-space data may be self-gated k-space data generated from nominally fully sampled k-space data using a projection-based self-navigator. An example method for generating 2D undersampled input images 208 is discussed below with respect to FIG. 4. The undersampled images 208 generated by the pre-processing module 212 may be stored in, for example, data storage 210 of system 200, data storage of an imaging system (e.g., disc storage 138 of MRI system 100 show in FIG. 1), or data storage of other computer systems (e.g., storage device 816 of computer system 800 shown in FIG. 8). In some embodiments, the undersampled images 208 (real and imaginary components), which have been acquired at multiple echo times, are stacked along the channel dimension or direction to, for example, exploit shared information and maintain consistency (e.g., of the magnitude and phase input information) along different contrasts which can be important for accurate parameter quantification. Accordingly, for the multi-echo undersampled images 208, images from different echoes (both real and imaginary components) may be stacked along the channel dimension.

The undersampled images 208 may be provided as an input to the two-stage deep learning network 202 (UP-Network or UP-Net). In some embodiments, the two-stage deep learning network 202 may be configured to perform undersampling artifact suppression, parameter mapping, and uncertainty estimation. As shown in FIG. 2, the two-stage deep learning network 202 can include a first stage or module implemented using an artifact suppression (or image enhancement) deep learning network (or neural network) 204 and a second stage or module implemented using a parameter mapping deep learning network (or neural network) 206. The input undersampled images 208 may be provided to the artifact suppression deep learning network 204. The artifact suppression deep learning network 204 is configured to generate at least one enhanced image 216 based on the input undersampled images 208, for example, the enhanced image(s) 216 may be multi-echo images with suppressed radial MR undersampling artifacts. In some embodiments, the enhanced images are 2D images or 3D images. In some embodiments, radial undersampling artifacts due to self-gating (e.g. radial streaking artifacts) may be suppressed. In some embodiments, for the multi-echo enhanced images 216, images from different echoes (both real and imaginary components) may be stacked along the channel dimension. The multi-echo enhanced images 216 may have the same data dimensions as the input multi-echo undersampled images 208.

In some embodiments, the artifact suppression deep learning network 204 may be a 2D convolutional neural network (CNN or ConvNet). In some embodiments, the artifact suppression deep learning network 204 may be implemented using known CNN models or network architectures such as, for example, two-dimensional U-Net. In some embodiments, the artifact suppression deep learning network 204 may be implemented as a residual U-Net architecture (i.e., a U-Net with a residual path) which can improve recognition and removal of radial undersampling artifacts. In some embodiments, the artifact suppression deep learning network 204 may be trained using a generative adversarial network (GAN) architecture or structure that can include a generative network (or generator) and a discriminative network (or discriminator). In some embodiments, instance normalization may be used in both the generator and discriminator to address image contrast variation across different subjects. The input/output dimensions of the artifact suppression deep learning network architecture (e.g., 2D U-Net) may be adapted to accommodate the multi-echo image datasets (e.g., multi-echo undersampled images 208 and multi-echo enhanced images 216). In some embodiments, the artifact suppression deep learning network 204 may use more complex network architectures (e.g., unrolled networks). In some embodiments, the artifact suppression deep learning network 204 may be implemented with three-dimensional deep learning neural networks and may be used with other types of deep learning neural networks. For these various deep learning network configurations, dimensions of the input undersampled images 208 can be adjusted accordingly.

The multi-echo enhanced images 216 generated by the artifact suppression deep learning network 204 may be provided as the input to the parameter mapping deep learning network 206. The parameter mapping deep learning network 206 may be configured to generate at least one quantitative parameter map 220 and an uncertainty map for each parameter. In some embodiments, the parameter mapping deep learning network 206 may be configured to generate quantitative proton-density fat fraction (PDFF) maps (e.g., from complex-valued fat and water signal components determined by the parameter mapping deep learning network 206), R₂* maps, and/or field maps (e.g., B₀ field maps) for liver fat and iron quantification. In some embodiments, the complex fat and water components, R₂* map, and field map may be stacked along the channel dimension. The parameter mapping deep learning network 206 is also configured to generate uncertainty maps 222 for corresponding quantitative parameter maps for each quantitative parameter. In some embodiments, the uncertainty maps corresponding to the quantitative parameter maps may be stacked along the channel dimension. In some embodiments, the uncertainty maps 222 are configured to estimate pixel-wise uncertainty levels (e.g., for example, detect regions with potential quantification errors) of corresponding quantitative parameter maps for each parameter. For example, an uncertainty map 222 may detect unreliable regions due to low signal-to-noise (SNR) in the input images and data. Accordingly, the uncertainty maps 222 may be used to provide a confidence level for each quantitative parameter. For example, the uncertainty estimation may be used to assess the level of confidence in the reconstruction and quantitative parameter mapping results of the two-stage deep learning network 202. Uncertainty estimation can advantageously provide context and assess confidence in the two-stage deep-learning network 202 outputs for clinical application that demand a high level of numerical accuracy, including the use of quantitative maps for diagnostic decisions. In some embodiments, the uncertainty maps 220 generated by the two-stage deep learning network 202 may be used to provide additional information and improve subsequent automatic MRI analysis, for example, deep learning-based segmentation, region of interest (ROI) selection, and disease classification. In some embodiments, other types of uncertainty, such as model uncertainty may be utilized.

In some embodiments, the parameter mapping deep learning network 206 may be a 2D convolutional neural network (CNN or ConvNet). In some embodiments, the parameter mapping deep learning network 206 may be implemented using known CNN models or network architectures such as, for example, two-dimensional U-Net. In some embodiments, the parameter mapping deep learning network 206 may be implemented as U-Net architecture with modified layers. In some embodiments, the parameter mapping deep learning network 206 may be implemented using a bifurcated U-Net structure that includes a shared encoder that extracts image features from the multi-contrast (e.g., multi-echo) enhanced images 216 and two decoders, namely, one decoder to calculate parameter maps (pixel-wise means) and one decoder to calculate uncertainty maps (pixel-wise variances) for each parameter. The input/output dimensions of the parameter mapping deep learning network 206 architecture (e.g., 2D U-Net) may be adapted to accommodate multi-echo image datasets (multi-echo enhanced images 216). In some embodiments, the artifact suppression deep learning network 204 may use more complex network architectures (e.g., unrolled networks with k-space data consistency layers). In some embodiments, the parameter mapping deep learning network 206 may be implemented with three dimensional deep learning neural networks and may be used with other types of deep learning neural networks. For these various deep learning network configurations, dimensions of the input multi-echo enhanced image(s) 216 can be adjusted accordingly.

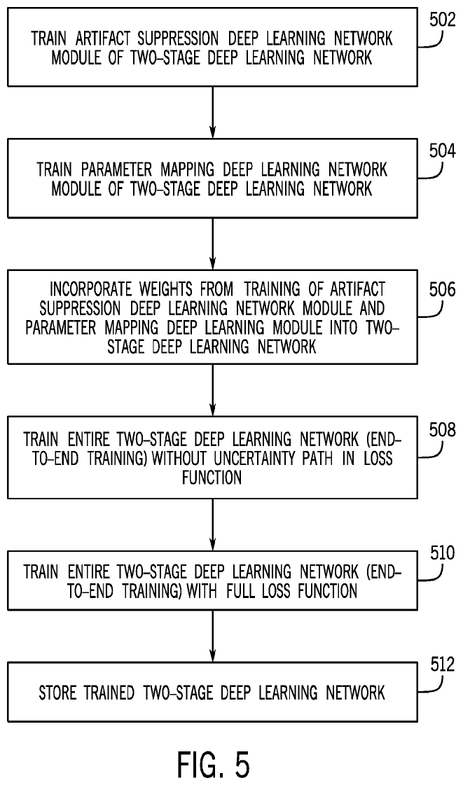

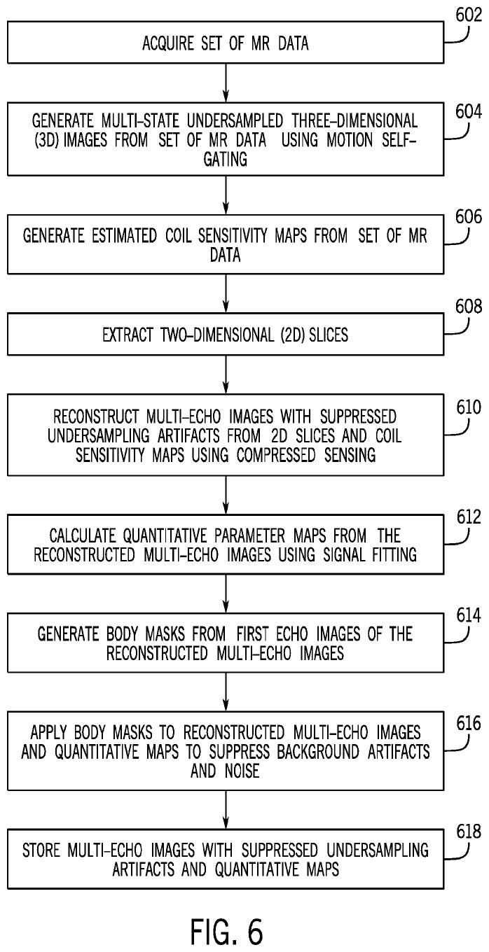

Advantageously, the two-stage deep learning network 202 is configured as a single end-to-end deep learning network architecture or framework with two concatenated stages 204, 206 that can utilize shared information between images and maps and accelerate the data acquisition and computational time for quantitative MRI, for example, free-breathing radial MRI liver fat and iron quantification. Accordingly, the system 200 can enable rapid quantitative MRI for clinical applications. The disclosed UP-Net 202 can accurately quantify parameters (e.g., PDFF, R₂*) from self-gated, free-breathing radial MR data without the need for data oversampling. Avoiding data oversampling can advantageously reduce the chances of bulk motion in prolonged scans, and shortened reconstruction time can advantageously improver clinical workflows by immediately providing results after scanning a subject. In some embodiments, the two-stage deep learning network 202, including each of the artifact suppression deep learning network 204 and the parameter mapping deep learning network 206, may be trained using known methods. In some embodiments, the two-stage deep learning network 202 may be trained using a supervised approach. An example method for training the two-stage deep learning network (UP-Network) is described below with respect to FIG. 5. As discussed further below, the loss function used for training the two-stage deep learning network 202 may include an MR physics loss term to guide quantitative mapping. The MR physics loss term ensure the quantification accuracy for parameter mapping during training. For example, in some embodiments, the MR physics loss term may be based on a fat-water and R₂* signal model. In some embodiments, the training data may include reference images generated by retrospectively undersampling fully sampled k-space data, and reference quantitative parameter maps generated using conventional signal fitting processes (e.g., graph-cut (GC) algorithms) on reconstructed reference images. In some embodiments, the training (or reference) images may be generated using free-breathing multi-echo stack-of-radial MR data from a plurality of subjects. In some embodiments, phase offset may be added to the training images and quantitative maps for data augmentation. An example method for generating training images and quantitative parameter maps for a training process for a deep learning network is discussed further below with respect to FIG. 6.

As mentioned above, the two-stage deep learning network 202 can generate one or more output(s) 218 including, for example, one or more enhanced image(s) with undersampling artifact suppression 216, one or more quantitative parameter map(s) 220 and one or more uncertainty map(s) 222. For example, in some embodiments, the two-stage deep learning network 202 may be configured to suppress undersampling artifacts to generate enhanced undersampling artifact suppressed images and to rapidly generate quantitative liver fat PDFF and R₂* maps with uncertainty estimation such as, for example, pixel-wise uncertainty maps. The outputs 218 may be displayed on a display 226 (e.g., displays 104, 136, 144 of the MRI system 100 show in FIG. 1 or display 818 of the computer system 800 shown in FIG. 8). The outputs 218 may also be stored in data storage, for example, data storage 228 (e.g., disc storage 138 of the MRI system 100 shown in FIG. 1 or device storage 816 of computer system 800 shown in FIG. 8).

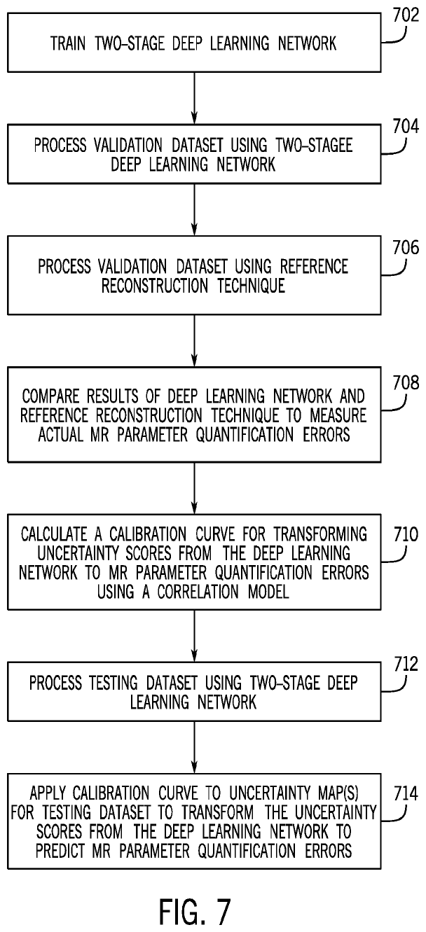

Post-processing module 224 may be configured to perform further processing on the outputs 218 of the two-stage deep learning network 202. In some embodiments, the post-processing module 224 may be configured to predict or detect parameter quantification errors using the uncertainty maps 222. Accordingly, the uncertainty map values (i.e., uncertainty scores) for individual parameters may be directly correlated with quantification errors. In some embodiments, a calibration method for the uncertainty maps 222 (or uncertainty scores) may be used to predict quantification errors (e.g., liver PDFF and R₂* quantification errors) in the quantitative parameter maps 220. For example, calibrated linear regression curves may be used to convert uncertainty scores to predicted quantification errors. An example method for calibrating uncertainty scores from a deep learning network and predicting actual errors for quantitative parameter mapping using the uncertainty scores is discussed further below with respect to FIG. 7. In some embodiments, the post-processing module 224 may be configured to generate confidence masks by thresholding the uncertainty scores of the uncertainty maps 222. The confidence masks may then be overlaid on the quantitative parameter maps. Radiologists can use the confidence masks to avoid making measurements and decisions in areas with higher uncertainty scores, and have more confidence in using the deep learning network 202 generated images (e.g., enhanced images 216) and quantitative maps (e.g., quantitative maps 220). The outputs of the post-processing module 224 may be displayed on the display 226. The outputs of the post-processing module 224 may also be stored in data storage, for example data storage 228.

In some embodiments, the two-stage deep learning network (UP-Net) 202 (including the artifact suppression deep learning network 204 and the parameter mapping deep learning network 206), the pre-processing module 212, and the post-processing module 224 may be implemented on one or more processors (or processor devices) of a computer system such as, for example, any general-purpose computing system or device, such as a personal computer, workstation, cellular phone, smartphone, laptop, tablet, or the like. As such, the computer system may include any suitable hardware and components designed or capable of carrying out a variety of processing and control tasks, including steps for receiving image(s) of the subject 208, implementing the two-stage deep learning network 202 (including the artifact suppression deep learning network 204 and the parameter mapping deep learning network 206), implementing pre-processing module 212, implementing post-processing module 224, providing the two-stage deep learning network output(s) 218 to a display 226 or storing the two-stage deep learning network output(s) 218 in data storage 228. For example, the computer system may include a programmable processor or combination of programmable processors, such as central processing units (CPUs), graphics processing units (GPUs), and the like. In some implementations, the one or more processor of the computer system may be configured to execute instructions stored in a non-transitory computer readable-media. In this regard, the computer system may be any device or system designed to integrate a variety of software, hardware, capabilities and functionalities. Alternatively, and by way of particular configurations and programming, the computer system may be a special-purpose system or device. For instance, such special-purpose system or device may include one or more dedicated processing units or modules that may be configured (e.g., hardwired, or pre-programmed) to carry out steps, in accordance with aspects of the present disclosure.

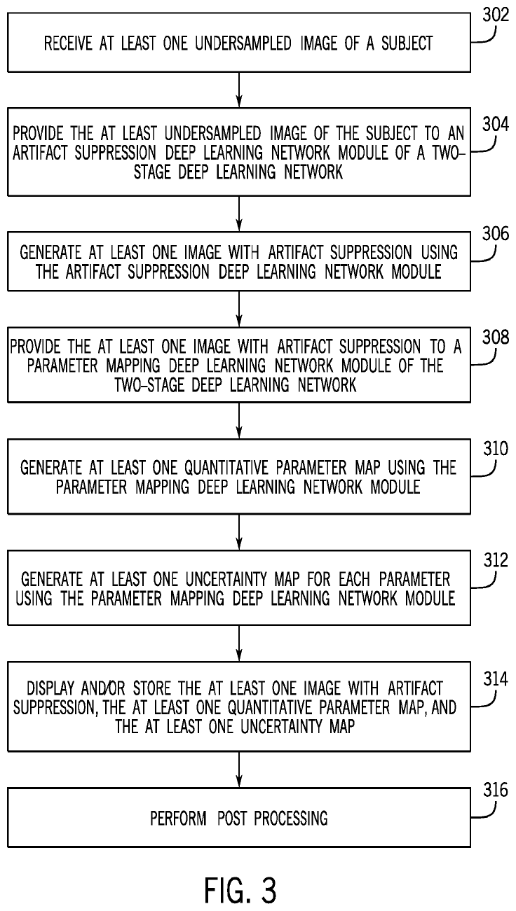

FIG. 3 illustrates a method for generating MR images, quantitative parameter maps, and uncertainty maps using a deep learning network in accordance with an embodiment. The process illustrated in FIG. 3 is described below as being carried out by the system 200 for generating MRI quantitative parameter maps using a deep learning network as illustrated in FIG. 2. Although the blocks of the process are illustrated in a particular order, in some embodiments, one or more blocks may be executed in a different order than illustrated in FIG. 3, or may be bypassed.

At block 302, at least one undersampled image 208 of a subject is received by the two-stage deep learning network 202. The undersampled input image(s) 208 of the subject may be magnetic resonance (MR) images acquired using an MRI system such as, for example, MRI system 100 shown in FIG. 1. In some embodiments, the undersampled input images 208 are 2D images, 3D images, or images of other dimensions. In some embodiments, the undersampled input images 208 are multi-contrast (e.g., multi-echo) MR images. In some embodiments, the undersampled input image(s) 208 may be retrieved from data storage (or memory) 210) of system 200, data storage of an imaging system (e.g., disc storage 138 of MRI system 100 show in FIG. 1), or data storage of other computer systems (e.g., storage device 816 of computer system 800 shown in FIG. 8). As discussed above with respect to FIG. 2, in some embodiments, the undersampled input images 208 may be acquired in real time from a subject using an MRI system (e.g., MRI system 100 shown in FIG. 1). For example, MR data 214 can be acquired from a subject using a pulse sequence performed on the MRI system and configured to acquire multi-contrast (e.g., multi-echo) MR data. For example, in some embodiments, a free-breathing multi-echo gradient-echo three-dimensional (3D) stack-of-radial pulse sequence can be used to acquire multi-echo radial MR data from a subject. The undersampled images 208 may be reconstructed (e.g., using the pre-processing module 214) from the acquired MR 214 data using, for example, known reconstruction methods. In some embodiments, the acquired MR data 214 is nominally fully sampled k-space data and the pre-processing module 212 can be configured to generate a set of undersampled k-space data which may then be used to reconstruct the undersampled images 208. In some embodiments, the acquired MR data 214 may be undersampled data or nominally oversampled data. Known methods may be used to generate the set of undersampled k-space data from the acquired k-space data. In some embodiments, the set of undersampled k-space data may be self-gated k-space data generated from nominally fully sampled k-space data using a projection-based self-navigator. An example method for generating the undersampled input images 208 is discussed below with respect to FIG. 4. The undersampled images 208 generated by the pre-processing module 212 may be stored in, for example, data storage 210 of system 200, data storage of an imaging system (e.g., disc storage 138 of MRI system 100 show in FIG. 1), or data storage of other computer systems (e.g., storage device 816 of computer system 800 shown in FIG. 8). In some embodiments, the undersampled images 208 (real and imaginary components), which have been acquired at multiple contrasts (e.g., multiple echo times), are stacked along the channel dimension or direction to, for example, exploit shared information and maintain consistency (e.g., of the magnitude and phase input information) along different contrasts which can be important for accurate parameter quantification. Accordingly, for the multi-contrast (e.g., multi-echo) undersampled images 208, images from different echoes (both real and imaginary components) may be stacked along the channel dimension.

At block 304, the at least one undersampled image 208 of the subject is provided to an artifact suppression deep learning network 204 module of the two-stage deep learning network 202. At block 306, at least one image with artifact suppression (e.g., enhanced image(s) 216) may be generated using the artifact suppression deep learning network 204 module. In some embodiments, the image(s) 216 with artifact suppression may be 2D multi-echo images with suppressed radial MR undersampling artifacts. In some embodiments, the image(s) 216 with artifact suppression may be 2D images or 3D images. In some embodiments, radial undersampling artifacts due to self-gating (e.g. radial streaking artifacts) may be suppressed. In some embodiments, for the multi-echo enhanced images 216, images from different echoes (both real and imaginary components) may be stacked along the channel dimension. The multi-echo enhanced images 216 may have the same data dimensions as the input multi-echo undersampled images 208.

At block 308, the at least one image with artifact suppression 216 may be provided to a parameter mapping deep learning network 206 module of the two-stage deep learning network 202. At block 310, at least one quantitative parameter map 220 may be generated using the parameter mapping deep learning network 206 module. In some embodiments, the parameter mapping deep learning network 206 may be configured to generate quantitative proton-density fat fraction (PDFF) maps (e.g., from complex-valued fat and water signal components determined by the parameter mapping deep learning network 206), R₂* maps, and/or field maps (e.g., B₀ field maps) for liver fat and iron quantification. In some embodiments, the complex-valued fat and water components, R₂* map, and field map may be stacked along the channel dimension.

At block 312, at least one uncertainty map 222 for each parameter may be generated using the parameter mapping deep learning network 206 module. In some embodiments, the uncertainty maps corresponding to the quantitative parameter maps may be stacked along the channel dimension. In some embodiments, the uncertainty maps 222 are configured to estimate pixel-wise uncertainty levels (e.g., for example, detect regions with potential quantification errors) of corresponding quantitative parameter maps for each parameter. For example, an uncertainty map 222 may detect unreliable regions due to low signal-to-noise (SNR) in the input images and data. Accordingly, the uncertainty maps 222 may be used to provide confidence for each quantitative parameter. For example, the uncertainty estimation may be used to assess the level of confidence in the reconstruction and quantitative parameter mapping results of the two-stage deep learning network 202. Uncertainty estimation can advantageously provide context and assess confidence in the two-stage deep-learning network 202 outputs for clinical application that demand a high level of numerical accuracy, including the use of quantitative maps for diagnostic decisions. In some embodiments, the uncertainty maps 220 generated by the two-stage deep learning network 202 may be used to provide additional information and improve subsequent automatic MRI analysis, for example, deep learning-based segmentation, region of interest (ROI) selection, and disease classification. In some embodiments, other types of uncertainty, such as model uncertainty may be utilized.

At block 314, the at least one image with artifact suppression 216, the at least one quantitative parameter map 220, and the at least one uncertainty map 222 for each parameter may be displayed on a display 226 (e.g., displays 104, 136, 144 of the MRI system 100 show in FIG. 1 or display 818 of the computer system 800 shown in FIG. 8). The at least one 2D image with artifact suppression 216, the at least one quantitative parameter map 220), and the at least one uncertainty map 222 may also be stored in data storage, for example, data storage 228 (e.g., disc storage 138 of the MRI system 100 shown in FIG. 1 or device storage 816 of computer system 800 shown in FIG. 8).

At block 316, post-processing may be performed (e.g., using post processing module 224) on the output(s) 218 (e.g., the at least one image with artifact suppression 216, the at least one quantitative parameter map 220, and the at least one uncertainty map 222 for each parameter) of the two-stage deep learning network 202. In some embodiments, the post-processing may include predicting or detecting parameter quantification errors using the uncertainty maps 222. Accordingly, the uncertainty map values (i.e., uncertainty scores) for individual parameters may be directly correlated with quantification errors. In some embodiments, a calibration method for the uncertainty maps 222 (or uncertainty scores) may be used to predict quantification errors (e.g., liver PDFF and R₂* quantification errors) in the quantitative parameter maps 220. For example, calibrated linear regression curves may be used to convert uncertainty scores to predicted quantification errors. An example method for calibrating uncertainty scores from a deep learning network and predicting actual errors for quantitative parameter mapping using the uncertainty scores is discussed further below with respect to FIG. 7. In some embodiments, confidence masks may be generated by thresholding the uncertainty scores of the uncertainty maps 222. The confidence masks may then be overlaid on the quantitative parameter maps. The results of the post-processing may be displayed on the display 226. The results of the post-processing may also be stored in data storage, for example data storage 228.

As mentioned above, undersampled images 208 may be provided as input to the UP-network 202. FIG. 4 illustrates a method for generating two-dimensional undersampled input images for an artifact suppression deep learning network in accordance with an embodiment. The process illustrated in FIG. 4 is described below as being carried out by the system 200 for generating MRI quantitative parameter maps using a deep learning network as illustrated in FIG. 2. Although the blocks of the process are illustrated in a particular order, in some embodiments, one or more blocks may be executed in a different order than illustrated in FIG. 4, or may be bypassed. At block 402, a set of MR data (e.g., k-space data) 214 may be acquired from a subject (e.g., a region of interest of a subject) using an MRI system (e.g., MRI system 100 shown in FIG. 1). For example, MR data 214 can be acquired from a subject using a pulse sequence performed on the MRI system and configured to acquire multi-contrast MR data. For example, in some embodiments, a free-breathing multi-echo gradient-echo three-dimensional (3D) stack-of-radial pulse sequence can be used to acquire multi-echo radial MR data from a subject. In some embodiments, the acquired MR data 214 may be nominally fully sampled data, undersampled data, or nominally oversampled data. The acquired MR data 214 may be stored in, for example, data storage 210) of system 200, data storage of an imaging system (e.g., disc storage 138 of MRI system 100 show in FIG. 1), or data storage of other computer systems (e.g., storage device 816 of computer system 800 shown in FIG. 8). At block 404, a set of undersampled MR data (or k-space data) may be generated, for example, using the pre-processing module 212, from the acquired set of k-space data. Known methods may be used to generate the set of undersampled k-space data from the acquired k-space data. In some embodiments, the set of MR data 214 may be retrospectively undersampled, for example, a projection-based self-navigator may be used to generate a set of self-gated k-space data from the acquired k-space data. In some embodiments, the self-gated k-space data (i.e., the set of undersampled k-space data) is generated using a 40% acceptance window with respect to the notion self-navigation signals.

At block 406, a set of three-dimensional (3D) undersampled multi-contrast (e.g., multi-echo) images may be reconstructed, for example, using the pre-processing module 212, from the set of undersampled MR data using, for example, known reconstruction methods. In some embodiments, the 3D undersampled images may be reconstructed using a non-uniform fast Fourier transform (NUFFT) and beamforming-based coil combination. At block 408, one or more 2D undersampled multi-contrast (e.g., multi-echo) images (or slices) 208 may be extracted, for example, using the pre-processing module 212, from the set of 3D undersampled multi-contrast (e.g., multi-echo) images. The 2D undersampled images 208 generated by the pre-processing module 212 may be stored in, for example, data storage 210 of system 200, data storage of an imaging system (e.g., disc storage 138 of MRI system 100 show in FIG. 1), or data storage of other computer systems (e.g., storage device 816 of computer system 800 shown in FIG. 8). As mentioned above, in some embodiments, the 2D undersampled input images 208 (real and imaginary components), which have been acquired at multiple echo times, may be stacked along the channel dimension or direction before being input into the UP-Net 202.

FIG. 5 illustrates an example method for training an uncertainty aware, physics-driven deep learning network (UP-Network, UP-Net) in accordance with an embodiment. The process illustrated in FIG. 5 is described below with reference to elements of the system 200 for generating MRI quantitative parameter maps using a deep learning network as illustrated in FIG. 2. Although the blocks of the process are illustrated in a particular order, in some embodiments, one or more blocks may be executed in a different order than illustrated in FIG. 5, or may be bypassed.

In the example training method of FIG. 5, the artifact suppression deep learning network 204 module and the parameter mapping deep learning network 206 module are each trained separately and then the entire two stage deep learning network 202 is trained (i.e., end-to-end training). In some embodiments, the overall two-stage deep learning network 202 may be trained using a loss function, LUP-Net, with 5 components for supervised training:

$${L}_{UP - Net} = {w}_{1} {L}_{imgMSE} + {w}_{2} {L}_{imgGAN} + {w}_{3} {L}_{mapMSE} + {w}_{4} {L}_{physics} + {w}_{5} {L}_{uncert} \qquad ( 3 )$$

where (1) L_{imgMSE}: mean-squared error (MSE) loss for images. (2) L_{mapMSE}: MSE loss for maps. (3) L_{imgGAN}: Wasserstein generative adversarial network (GAN) loss for images. (4) L_{physics}=mean(∥\hat{m}−Q(\hat{p})∥²) which represents the MR physics loss where Q synthesizes multi-echo images from output quantitative maps based on an MRI fat/water/R₂* model. (5)

$${L}_{uncertinty} = \frac{{‖ \hat{p} - p ‖}_{1}}{\hat{u}} + log ( \hat{u} )$$

which represents aleatoric uncertainty loss based on a Laplace distribution. The terms (w₁˜w₅) are the relative weights for each loss component in Eqn. 3. In some embodiments, as described below; the artifact suppression deep learning network 204 and the parameter mapping deep learning network 206 may be separately trained using loss functions including a subset of these five components. Advantageously, an MR physics loss term may be included to guide quantitative mapping and can improve image quality and ensure the accuracy for parameter mapping during training. For example, in some embodiments, the MR physics loss term may be based on a fat-water and R₂* signal model.

At block 502, the artifact suppression deep learning network 204 module of the two-stage deep learning network 202 is trained. The training data for the artifact suppression deep learning network 204 can include pairs of multi-contrast (e.g., multi-echo) undersampled images and reference images. In some embodiments, a phase augmentation strategy may be used to increase the amount of training data, for example, phase offsets may be added to the training images and quantitative maps for data augmentation. In some embodiments, the phase offset may be randomly selected between 0˜2π. In some embodiments, the artifact suppression deep learning network 204 may be trained using an Adam optimizer. The artifact suppression deep learning network 204 may be trained using a loss function including an image mean squared error (MSE) loss and a Wasserman GAN loss. An image mean square error (MSE) loss may be used to measure the errors between enhanced (m) and reference (m) multi-echo images, as given by:

$${L}_{imgMSE} = \frac{1}{{N}_{j}} {\sum }_{j} {( {\hat{m}}_{j} - {m}_{j} )}^{2} \qquad ( 4 )$$

where j represents the pixel index and N is the total number of pixels in the multi-echo images.
A Wasserstein GAN loss may be used for training the GAN network in the artifact suppression deep learning network 204, as given by:

$${min}_{G} {max}_{D} {𝔼}_{m ∼ {p}_{train} ( m )} [ D ( m ) ] - {𝔼}_{\hat{m} ∼ {p}_{G} ( \hat{m} )} [ D ( G ( \hat{m} ) ) ] , \qquad ( 5 )$$

where G represents the generator, D represents the discriminator. For the generator updates, the following loss function may be used:

$${L}_{imgGan} = {𝔼}_{\hat{m} ∼ {p}_{G} ( \hat{m} )} [ D ( G ( \hat{m} ) ) ] \qquad ( 6 )$$

At block 504, the parameter mapping deep learning network 206 module of the to-stage deep learning network 202 is trained. The training data for the parameter mapping deep learning network 206 can include pairs of reference multi-contrast images and reference quantitative maps. In some embodiments, a phase augmentation strategy may be used to increase the amount of training data, for example, phase offsets may be added to the training images and quantitative maps for data augmentation. In some embodiments, the phase offset may be randomly selected between 0˜2π. In some embodiments, the parameter mapping deep learning network 206 may be trained using an Adam optimizer. The parameter mapping deep learning network 206 may be trained using a loss function including a map mean squared error (MSE) loss and an MRI physics loss based on a quantitative signal model. A map MSE loss may be used to measure the errors between quantitative maps from UP-Net (\hat{p}) and reference data (p), as given by:

$${L}_{mapMSE} = \frac{1}{{N}_{j}} {\sum }_{j} {( {\hat{p}}_{j} - {p}_{j} )}^{2} \qquad ( 7 )$$

An MRI physics loss based on the quantitative signal model may be given by:

$${L}_{physics} = \frac{1}{{N}_{j}} {( \hat{m} - Q ( \hat{p} ) )}^{2} \qquad ( 8 )$$

where Q represents an operator that transforms the quantitative maps to multi-echo images based on the MRI signal equation. In some embodiments where the network 206 is used for PDFF and R₂* quantification, the Q operator used may be:

$$Q ( \hat{p} ) = Q ( W , F , {R}_{2}^{*} , φ , TE ) = ( W + F \cdot ( {\sum }_{m = 1}^{M} {a}_{m} \cdot {e}^{i 2 π {f}_{m} TE} ) ) \cdot {e}^{- {R}_{2}^{*} TE} \cdot {e}^{i 2 π φ TE} \qquad ( 9 )$$

where W, F, R₂, φ represent the 2D quantitative water maps, fat maps, R₂* maps, and B₀ field maps. In such embodiments, a 7-peak fat model with amplitudes am and frequencies fₘ may be included in the Q operator.

At block 506, the weights generated at block 502 and 504 by training each of the artifact suppression deep learning network 204 module and the parameter mapping deep learning network module 206 are incorporated into the two-stage deep learning network 202. At block 508, the entire two-stage deep learning network 202 is trained (i.e., end-to-end training) without the uncertainty path and uncertainty loss component in the loss function. The training data for the end-to-end training of the two-stage deep learning network 202 (without the uncertainty path) can include training sets of undersampled images, reference images, and reference quantitative parameter maps. In some embodiments, a phase augmentation strategy may be used to increase the amount of training data, for example, phase offsets may be added to the training images and quantitative maps for data augmentation. In some embodiments, the phase offset may be randomly selected between 0˜2 nt. In some embodiments, the two-stage deep learning network 202 may be trained using an Adam optimizer. The end-to-end training of the two-stage deep learning network 202 without the uncertainty path may be performed using a loss function including the image mean squared error (MSE) loss, L_{imgMSE} (Eqn.4), the Wasserman GAN loss, L_{imgGAN} (Eqns. 5 and 6), the map mean squared error (MSE) loss, L_{mapMSE} (Eqn. 7), and the MR physics loss, L_{physics} (Eqn. 8).

At block 510, the entire two-stage deep learning network 202 is trained (i.e., end-to-end training) with the full loss function in Eqn. 3. The training data for the end-to-end training of the two-stage deep learning network 202 can include training sets of undersampled images, reference images, and reference quantitative parameter maps. In some embodiments, a phase augmentation strategy may be used to increase the amount of training data, for example, phase offsets may be added to the training images and quantitative maps for data augmentation. In some embodiments, the phase offset may be randomly selected between 0˜2π. In some embodiments, the two-stage deep learning network 202 may be trained using an Adam optimizer. The end-to-end training of the two-stage deep learning network 202 may be performed using the full loss function including the image mean squared error (MSE) loss, L_{imgMSE} (Eqn. 4), the Wasserman GAN loss, L_{imgGAN} (Eqns. 5 and 6), the map mean squared error (MSE) loss, L_{mapMSE} (Eqn 7), the MR physics loss, L_{physics} (Eqn. 8) and an uncertainty loss. The uncertainty loss may be used to predict quantitative parameter outputs with corresponding uncertainty scores (or maps). In some embodiments, the uncertainty loss may be given by:

$${L}_{uncertainty} = \frac{{‖ \hat{p} - p ‖}_{1}}{\hat{u}} + log ( \hat{u} ) \qquad ( 10 )$$

where p denotes the network output, p denotes the reference parameter maps, and û denotes the uncertainty map or estimation. The uncertainty loss function in Eqn. 10 is equivalent to performing maximum a posteriori (MAP) inference where a Laplace distribution is assumed for each quantitative parameter in each pixel. In regions where the ∥\hat{p}−p∥₁ error minimization is difficult (e.g., regions with lower signal-to-noise ratio), increased values of û can reduce the loss, therefore capturing uncertainty. The log(û) term can serve as a regularization term to avoid unconstrained increase in the uncertainty score. Because the uncertainty score, or the variance of a distribution, should always be nonnegative, in some embodiments, a softplus layer (Softplus(x)=log(1+e^{x})) can be added prior to the output of û to generate positive values.

At block 512, the trained two-stage deep learning network 202 may be stored in data storage such as, for example, data storage of an imaging system (e.g., data storage an operator workstation 102, 142 of MRI system 100 show in FIG. 1), or data storage of other computer systems (e.g., storage device 816 of computer system 800 shown in FIG. 8).

Due to the challenge of obtaining fully-sampled self-gated free-breathing radial images and imaging data, in some embodiments, training images and corresponding quantitative parameter maps may be generated using constrained reconstruction and MR signal fitting techniques (e.g., compressed sensing and graph-cut algorithms, respectively). FIG. 6 illustrates an example method for generating training images and quantitative parameter maps for a training process for a deep learning network in accordance with an embodiment. Although the blocks of the process are illustrated in a particular order, in some embodiments, one or more blocks may be executed in a different order than illustrated in FIG. 6, or may be bypassed. At block 602, a set of MR data may be acquired from a plurality of subjects using an MRI system (e.g., MRI system 100 shown in FIG. 1). In some embodiments, the set of MR data may be retrieved from data storage such as, for example, data storage of an imaging system (e.g., data storage of MRI system 100 show in FIG. 1), or data storage of other computer systems (e.g., storage device 816 of computer system 800 shown in FIG. 8). In some embodiments, the set of MR data may be nominally fully sampled free-breathing multi-echo stack-of-radial MR data acquired from a plurality of subjects.

At block 604, multi-state 3D images may be generated from the acquired set of MR data using motion self-gating. For example, a projection-based self-navigator from the kₓ=k_{y}=0 line in k-space may be extracted to track respiratory motion along the z dimension. In some embodiments, a sliding window approach may be applied along the motion dimension to bin the k-space data into a plurality respiratory motion states (e.g., 6 motion states) where each bin contained 40% of the entire k-space data (effective data undersampling factor=2.5 in each state). In this example, the amount of data shared between neighboring motion states was 28% of the entire k-space data. At block 606, estimated coil sensitivity maps may be generated using the acquired set of MR data. In some embodiments, the coil sensitivity maps may be estimated using a phased array beamforming technique, which can be used to suppress the radial artifacts resulting from hardware imperfections (e.g., gradient non-linearity and field inhomogeneity). At block 608, 2D slices (or images) may be extracted from the multi-stage 3D images using known extraction methods.

At block 610, motion self-gated multi-echo images with suppressed undersampling artifacts may be reconstructed from the 2D slices and coil sensitivity maps using compressed sensing. For example, in some embodiments, the CS reconstruction may be performed by solving:

$${x}^{*} = arg {min}_{x} {‖ FSx - y ‖}_{2}^{2} + {λ}_{1} {TV}^{motion} ( x ) + {λ}_{2} {\sum }_{echo , state} {‖ Wavelet ( {x}_{echo , state} ) ‖}_{1} \qquad ( 11 )$$

where F represents the non-uniform fast Fourier Transform (NUFFT) operator, S denotes beamforming-base coil sensitivity maps, x is the reconstructed multi-echo images, y is the acquired multi-channel multi-echo stack-of-radial k-space data, λ₁ and λ₂ are regularization parameters. In some embodiments, the regularization parameters may be chosen manually to balance between undersampling artifact reduction and image sharpness. At block 612, quantitative parameter maps (e.g., complex-valued fat/water components, R₂* map, and B₀ field map) may be calculated from the reconstructed multi-echo images using signal fitting. For example, reference quantitative maps may be generated by fitting reference multi-echo images reconstructed at block 610 to a multi-peak fat model with a single R₂* component using graph cut (GC)-based algorithms.

At block 614, body masks may be generated from first echo images of the reconstructed multi-echo magnitude images. The body masks are configured to suppress the residual radial undersampling artifacts in the background in both images and quantitative maps. At block 616, the body masks may be applied to the reconstructed multi-echo image and corresponding quantitative maps to suppress background artifacts and noise. At block 618, reference data (i.e., the multi-echo images with suppressed undersampling artifacts and quantitative maps) may be stored in data storage such as, for example, data storage 210) of the system 200 shown in FIG. 2, data storage of an imaging system (e.g., data storage of MRI system 100 show in FIG. 1), or data storage of other computer systems (e.g., storage device 816 of computer system 800 shown in FIG. 8).

FIG. 7 illustrates a method for calibrating uncertainty scores from a deep learning network and predicting actual errors for quantitative parameter mapping using the uncertainty scores in accordance with an embodiment. The process illustrated in FIG. 7 is described below with reference to elements of the system 200 for generating MRI quantitative parameter maps using a deep learning network as illustrated in FIG. 2. Although the blocks of the process are illustrated in a particular order, in some embodiments, one or more blocks may be executed in a different order than illustrated in FIG. 7, or may be bypassed.

At block 702, a two-stage deep learning network (e.g., two-stage deep learning network 202) may be trained, for example using the method descried above with respect to FIG. 5. At block 704, a validation dataset (i.e., a dataset with known quantitative parameters) is processed with the two-stage deep learning network 202 to produce outputs 218 such as the artifact suppressed images 216, quantitative parameter maps 220 and uncertainty maps 222. The uncertainty scores (i.e., the uncertainty map values from uncertainty map(s) 222) from the two-stage deep learning network 202 are also measured for the validation dataset. At block 706, the validation dataset is processed using a reference quantitative reconstruction technique (e.g., compressed sensing) to generate quantitative parameter maps. At block 708, quantification errors between the quantitative maps 220 generated by the two-stage deep learning network 202 and the quantitative maps generated by the reference reconstruction technique are measured for the validation dataset by comparing the quantitative maps 220 generated by the two-stage deep learning network 202 and the quantitative maps generated by the reference reconstruction technique. At block 710, a calibration curve may be calculated from the measured quantification errors and uncertainty scores for the validation dataset using a correlation model (e.g., calibrated linear regression). The calibration curve may be configured to transform the uncertainty scores from the deep learning network 202 to MR parameter quantification errors. At block 712, a testing data set (e.g., a set of new data for a subject or data for which quantitative parameter information is not known) may be processed by the two-stage deep learning network 202 to generate outputs such as artifact suppressed images 216, quantitative parameter maps 220 and uncertainty maps 222. At block 714, the calibration curve may be applied to the uncertainty scores for the testing dataset from the two-stage deep learning network 202 to transform the uncertainty scores into predicted quantification errors.

FIG. 8 is a block diagram of an example computer system in accordance with an embodiment. Computer system 800 may be used to implement the systems and methods described herein. In some embodiments, the computer system 800 may be a workstation, a notebook computer, a tablet device, a mobile device, a multimedia device, a network server, a mainframe, one or more controllers, one or more microcontrollers, or any other general-purpose or application-specific computing device. The computer system 800 may operate autonomously or semi-autonomously, or may read executable software instructions from the memory or storage device 816 or a computer-readable medium (e.g., a hard drive, a CD-ROM, flash memory), or may receive instructions via the input device 820 from a user, or any other source logically connected to a computer or device, such as another networked computer or server. Thus, in some embodiments, the computer system 800 can also include any suitable device for reading computer-readable storage media.

Data, such as data acquired with an imaging system (e.g., an OCT imaging system, a CT imaging system, a magnetic resonance imaging (MRI) system, etc.) may be provided to the computer system 800 from a data storage device 816, and these data are received in a processing unit 802. In some embodiment, the processing unit 802 includes one or more processors. For example, the processing unit 802 may include one or more of a digital signal processor (DSP) 804, a microprocessor unit (MPU) 806, and a graphics processing unit (GPU) 808. The processing unit 802 also includes a data acquisition unit 810 that is configured to electronically receive data to be processed. The DSP 804, MPU 806, GPU 808, and data acquisition unit 810 are all coupled to a communication bus 812. The communication bus 812 may be, for example, a group of wires, or a hardware used for switching data between the peripherals or between any component in the processing unit 802.

The processing unit 802 may also include a communication port 814 in electronic communication with other devices, which may include a storage device 816, a display 818, and one or more input devices 820. Examples of an input device 820 include, but are not limited to, a keyboard, a mouse, and a touch screen through which a user can provide an input. The storage device 816 may be configured to store data, which may include data such as, for example, acquired data, acquired images, artifact suppressed images, quantification maps, and uncertainty maps, whether these data are provided to, or processed by, the processing unit 802. The display 818 may be used to display images and other information, such as magnetic resonance images, patient health data, and so on.

The processing unit 802 can also be in electronic communication with a network 822 to transmit and receive data and other information. The communication port 814 can also be coupled to the processing unit 802 through a switched central resource, for example the communication bus 812. The processing unit can also include temporary storage 824 and a display controller 826. The temporary storage 824 is configured to store temporary information. For example, the temporary storage 824 can be a random access memory.

Computer-executable instructions for quantitative MRI using a two-stage deep learning network according to the above-described methods may be stored on a form of computer readable media. Computer readable media includes volatile and nonvolatile, removable, and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital volatile disks (DVD) or other optical storage, magnetic cassettes, magnetic tape, magnetic disk storage or other magnetic storage devices, or any other medium which can be used to store the desired instructions and which may be accessed by a system (e.g., a computer), including by internet or other computer network form of access.

The present invention has been described in terms of one or more preferred embodiments, and it should be appreciated that many equivalents, alternatives, variations, and modifications, aside from those expressly stated, are possible and within the scope of the invention.

1. A method for generating magnetic resonance imaging (MRI) quantitative parameter maps, the method comprising:
receiving at least one multi-contrast magnetic resonance (MR) image of a subject;
providing the at least one multi-contrast MR image of the subject to an artifact suppression deep learning network of a two-stage deep learning network;
generating at least one multi-contrast MR image with suppressed undersampling artifacts using the artifact suppression deep learning network to suppress undersampling artifacts in the at least one multi-contrast MR image of the subject;
providing the at least one multi-contrast MR image with suppressed undersampling artifacts to a parameter mapping deep learning network of the two-stage deep learning network;
generating at least one quantitative MR parameter map based on the at least one multi-contrast MR image with suppressed undersampling artifacts using the parameter mapping deep learning network;
generating an uncertainty estimation map for the at least one quantitative MR parameter map using the parameter mapping deep learning network; and
displaying at least one of the at least one multi-contrast MR image with suppressed undersampling artifacts, the at least one quantitative MR parameter map, and the corresponding uncertainty estimation map on a display.

2. The method according to claim 1, wherein one or more of the at least one multi-contrast MR image and at least one multi-contrast MR image with suppressed undersampling artifacts are multi-echo MR images.

3. The method according to claim 1, wherein the artifact suppression learning network is a convolutional neural network.

4. The method according to claim 1, wherein the parameter mapping deep learning network is a convolutional neural network.

5. The method according to claim 1, wherein the at least one multi-contrast MR image is a plurality of multi-contrast MR images reconstructed from undersampled k-space data.

6. The method according to claim 5, wherein the plurality of multi-contrast MR images are stacked along the channel dimension.

7. The method according to claim 1, wherein the at least one quantitative MR parameter map is a plurality of quantitative MR parameter maps, wherein each quantitative MR parameter map corresponds to a different quantitative parameter.

8. The method according to claim 7, wherein each quantitative MR parameter map in the plurality of quantitative MR parameter maps is stacked along the channel dimension.

9. The method according to claim 7, wherein each quantitative MR parameter map in the plurality of quantitative MR parameter maps has a corresponding uncertainty estimation map.

10. The method according to claim 1, wherein the two-stage deep learning network is trained using a loss function that comprises a MR physics loss term.

11. The method according to claim 1, further comprising predicting MR parameter quantification error using the at least one uncertainty map.

12. The method according to claim 1, wherein the at least one quantitative MR parameter map includes a proton-density fat fraction (PDFF) map, a R₂* map, and a B₀ field map.

13. The method according to claim 1, wherein the quantitative MR parameter is one of T₁, T₂, stiffness, susceptibility, diffusion, chemical exchange, or magnetization transfer.

14. The method according to claim 1, wherein the at least one multi-contrast MR image is acquired using an undersampled free-breathing multi-echo stack-of-radial MRI acquisition.

15. A system for magnetic resonance imaging (MRI) quantitative parameter maps comprising:
an input for receiving at least one multi-contrast magnetic resonance (MR) image of a subject;
a two-stage deep learning network comprising:
an artifact suppression deep learning network configured to generate at least one multi-contrast MR image with suppressed undersampling artifacts using the at least one multi-contrast MR image of the subject; and
a parameter mapping deep learning network coupled to the artifact suppression deep learning network, the parameter mapping deep learning network configured to generate at least one quantitative MR parameter map based on the at least one multi-contrast MR image with suppressed undersampling artifacts and to generate an uncertainty estimation map for the at least one quantitative MR parameter map; and
a display coupled to the two-stage deep learning network and configured to display at least one of the at least one multi-contrast MR image with suppressed undersampling artifacts, the at least one quantitative MR parameter map, and the corresponding uncertainty estimation map.

16. The system according to claim 15, wherein one or more of the at least one multi-contrast MR image and at least one multi-contrast MR image with suppressed undersampling artifacts are multi-echo MR images.

17. The system according to claim 15, further comprising a pre-processing module coupled to the two-stage deep learning network and configured to generate the at least one multi-contrast MR image of the subject from undersampled k-space data.

18. The system according to claim 17, wherein the undersampled k-space data is acquired using a self-gating free-breathing multi-echo stack-of-radial MRI acquisition.

19. The system according to claim 15, further comprising a post-processing module coupled to the two-stage deep learning network and configured to predict MR parameter quantification error using the at least one uncertainty map.

20. The system according to claim 15, wherein the artifact suppression learning network is a convolutional neural network.

21. The system according to claim 15, wherein the parameter mapping deep learning network is a convolutional neural network.

22. The system according to claim 15, wherein the two-stage deep learning network is trained using a loss function that comprises a MR physics loss term.

23. The system according to claim 15, wherein the at least one quantitative MR parameter map includes a proton-density fat fraction (PDFF) map, a R₂* map, and a B₀ field map.

24. The system according to claim 15, wherein the quantitative MR parameter is one of T₁, T₂, stiffness, susceptibility, diffusion, chemical exchange, or magnetization transfer.
